(19) United States
(12) Patent Application Publication
(10) Pub. No.: US 2014/0061950 A1
(43) Pub. Date: Mar. 6, 2014

(54) STACKABLE FLIP CHIP FOR MEMORY PACKAGES

(71) Applicant: Jun Zhai, San Jose, CA (US)

(72) Inventor: Jun Zhai, San Jose, CA (US)

(21) Appl. No.: 13/605,263

(22) Filed: Sep. 6, 2012

(51) Int. Cl. H01L 23/522; H01L 21/50

(52) U.S. Cl. 257/777; 438/107; 438/108; 257/E23.142; 257/E21.499

(57) ABSTRACT

In one embodiment, an electronic memory module may be provided to couple two or more stacked memory dies. The memory module may include a first substrate that couples the first memory die in a flip chip configuration. The substrate also includes connectors to couple to a second substrate, which has a flip chip connection to a second memory die. A surface of the first substrate opposite the flip chip connection of the first memory die may include connectors to couple to the first memory die (through the first substrate) and may include connectors to couple to the second memory die (through the connectors that couple to the second substrate, and through the first substrate.

### BACKGROUND

1. Technical Field

This disclosure relates generally to semiconductor devices, and more particularly to stackable die modules.

2. Description of the Related Art

Increasing demand of memory bandwidth imposes significant challenges to maintaining the signal integrity of memory channels within the packages. Typical DDR packages use wires to couple the silicon input/output (I/O) pads to substrates (e.g., wirebond packages). To increase the memory capacity per package, two dies are often stacked to double the capacity. However, the wire loops that connect the two dies to the substrate result in large loop inductance, and hence cause voltage noise and poor signal integrity. Also the wirebonds limit the number of I/Os and power delivery.

Flip chip packages provide a much shorter impedance and more I/Os and power/ground pins. However, flip chip packages are limited to a mono-die solution. Currently there is no known solution to stack multiple dies all through flip chip bumps except using through-silicon vias (TSV)/ubump configurations that are adopted for wide-IO DRAM. TSV technology is somewhat unproven, costly, and complex.

### SUMMARY

In one embodiment, an electronic memory module may be provided to couple two or more stacked memory dies. The memory module may include a first substrate that couples the first memory die in a flip chip configuration. The substrate also includes connectors to couple to a second substrate, which has a flip chip connection to a second memory die. A surface of the first substrate opposite the flip chip connection of the first memory die may include connectors to couple to the first memory die (through the first substrate) and may include connectors to couple to the second memory die (through the connectors that couple to the second substrate, and through the first substrate.

In an embodiment, an electronic memory module, and method of making same, including at least two stacked dies are disclosed. An electronic memory module may include a first substrate including a first surface, a second surface substantially opposite of the first surface, and a first set of electrical conductors. The first set of electrical conductors may be coupled to the first surface. The first set of electrical conductors may function to electrically connect the electronic memory module to a circuit board and/or other devices. The electronic memory module may include a first die electrically connected to the second surface of the first substrate using a second set of electrical conductors. The second set of electrical conductors may function to electrically connect to at least some of the first set of electrical conductors. The electronic memory module may include a third set of electrical conductors coupled to the second surface of the first substrate. The third set of electrical conductors are configured to electrically connect to at least some of the first set of electrical conductors.

### BRIEF DESCRIPTION OF THE DRAWINGS

The following detailed description makes reference to the accompanying drawings, which are now briefly described.

FIG. 1 depicts an embodiment of an electronic memory module including two dies stacked one on top of the other. At least some of the electrical conductors are not depicted for the sake of clarity.

FIG. 2 depicts an embodiment of an electronic memory module including three dies stacked one on top of the other. At least some of the electrical conductors are not depicted for the sake of clarity.

FIG. 3 depicts an embodiment of a top view of an electronic memory module. At least one die is depicted (using broken lines) as seen through insulating compound.

FIG. 4 depicts an embodiment of a bottom view of an electronic memory module.

FIG. 5 depicts an embodiment of a portion of an electronic memory module including at least four dies in a fan-out configuration. At least some of the electrical conductors are not depicted for the sake of clarity. Only two die are depicted in FIG. 5 for the sake of clarity.

FIG. 6 depicts an embodiment of a top view of an electronic memory module. At least four dies are depicted (using broken lines) in a fan-out configuration as seen through insulating compound.

FIG. 7 depicts an embodiment of a top perspective view of an electronic memory module mounted on a motherboard.

FIG. 8 depicts an embodiment of a first stage of a method of producing an electronic memory module.

FIG. 9 depicts an embodiment of a second stage of a method of producing an electronic memory module.

FIG. 10 depicts an embodiment of a third stage of a method of producing an electronic memory module.

FIG. 11 depicts an embodiment of a fourth stage of a method of producing an electronic memory module.

FIG. 12 depicts an embodiment of a fifth stage of a method of producing an electronic memory module.

FIG. 13 depicts an embodiment of flow chart representing a method of forming at least a portion of an electronic memory module.

Specific embodiments are shown by way of example in the drawings and will be described herein in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

The headings used herein are for organizational purposes only and are not meant to be used to limit the scope of the description. As used throughout this application, the word “may” is used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third die electrically connected to the module substrate” does not preclude scenarios in which a “fourth die electrically connected to the module substrate” is connected prior to the third die, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. §112, paragraph six, interpretation for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

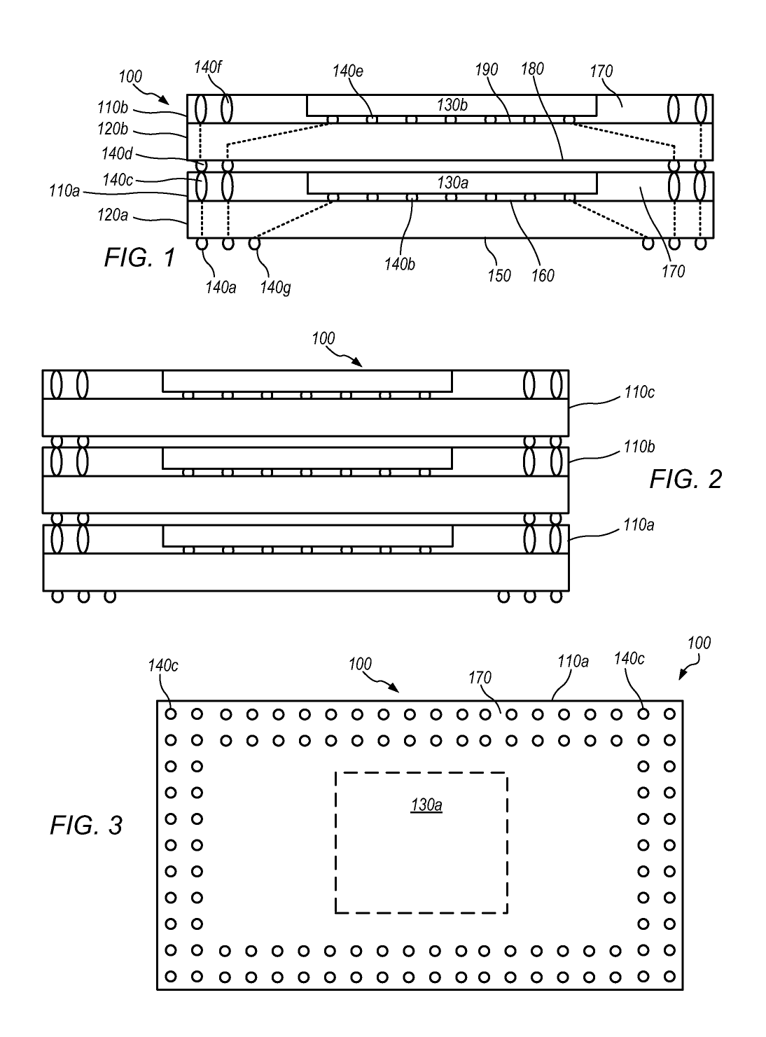

Turning to FIG. 1-FIG. 4, depict various embodiments of an electronic memory module 100. Electronic memory module 100 may include two or more packages 110a-110b. FIG. 1 depicts an embodiment of two packages 110a-b stacked to form electronic memory module 100. FIG. 2 depicts an embodiment of three packages 110a-c stacked to form electronic memory module 100. It should be noted that at least some of the elements of the electronic memory module 100 are not depicted in some of the figures for the sake of clarity (e.g., many of the electrical conductors are not displayed in FIG. 1 and FIG. 2 for the sake of clarity).

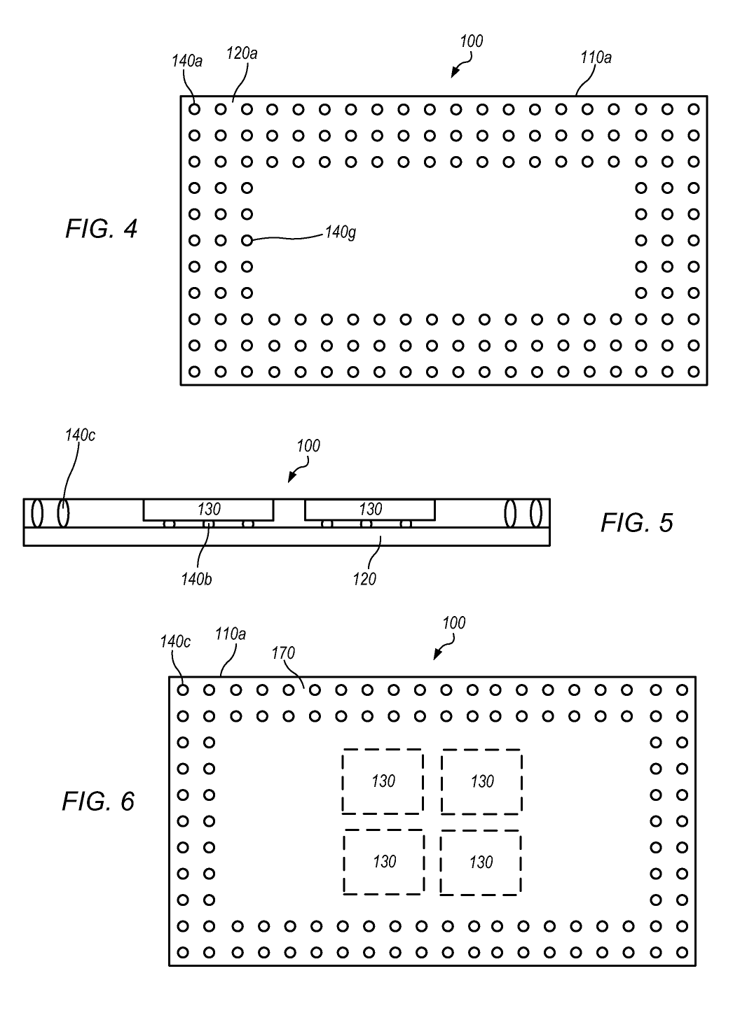

In some embodiments, package 110a may include a substrate 120a, a die 130a, and multiple sets of electronic conductors 140. Substrate 120a may include a first surface 150 and a second surface 160. The first and second surface of the substrate may be positioned opposite one another. The first surface may include a first set of electrical conductors 140a. The first set of electrical conductors 140a may function to couple package 110a to another electronic module and/or component. FIG. 4 depicts an embodiment of a bottom view of an electronic memory module including first substrate 120a and first set of electrical conductors 140a. The conductors 140a may be part of a ball grid array (BGA) package in the illustrated embodiment. Thus, the conductors 140a may be solder balls that may be reflowed to couple to memory module 100 to a circuit board or other component (such as a system on a chip (SOC) in a package-on-package configuration).

Package 110a may include a first die 130a electrically connected to the second surface of the first substrate. In some embodiments, a die may be connected to a substrate using a second set of electrical conductors 140b. The second set of electrical conductors may function to electrically connect to at least some of the first set of electrical conductors. More particularly, in an embodiment, the electrical conductors 140b may be controlled-collapse chip connection (C4) bumps that are patterned on the die 130a during manufacture of the die 130a. The electrical conductors 140b may be reflowed onto pads on the second surface of the substrate 120a using flip-chip connection techniques. The substrate 120a may connect the conductors 140b to connectors 140g on the first surface of the substrate 120a. FIG. 4 also illustrates the conductors 140g. Accordingly, the second surface of the substrate 120a may include conductors to couple each die in the stacked package 100 to a circuit board or other components. The conductors 140g, like the conductors 140a described above, may be solder balls using a BGA packaging technique.

In some embodiments, package 110a may include a third set of electrical conductors 140c. The third set of electrical conductors may be coupled to the second surface of the first substrate. The third set of electrical conductors 140c may function to electrically connect to at least some of the first set of electrical conductors 140a. Thus, the substrate 120a may include electrical connection between the conductors 140a and 140c, and between the conductors 140b and 140g. The connection is illustrated as dotted lines in FIG. 1. The connection as shown may be the logical view of the connection, the actually physical routing of conductors may be different. For example, the substrate 120a may be printed circuit board (PCB) technology in which alternating layers of wiring and insulator (with vias through the insulator to connect between wiring layers).

In some embodiments, package 110a may include a compound 170 (often referred to as a mold underfill compound) to substantially cover the second surface of the first substrate. The compound may at least substantially cover the first die. The compound may substantially cover most of the third set of electrical conductors. In some embodiments, the compound may include an insulating compound which functions to substantially encapsulate at least an upper portion of the package.

The third set of electrical conductors may have a first side and a second side. The first side may be in contact with the second surface of the first substrate. The second side may be positioned opposite the first side and be substantially exposed (i.e., not covered and/or encapsulated by insulating compound 170). FIG. 3 depicts an embodiment of a top view of a first package of an electronic memory module depicting electrical conductors exposed through insulating compound. At least one die is depicted (using broken lines) as seen through the insulating compound 170. Exposing at least a portion of the third set of conductors may allow the third set of conductors to electrically couple package 110a to another electronic module or component. The third set of conductors may electrically couple an electronic module or component to another electronic module or component through the first set of electrical conductors. In an embodiment, the insulating compound 170 may be initially applied to the package 110a and may cover the conductors 140c. The conductors 140c may exposed using laser drilling, polishing, etc.

In some embodiments, the third set of electrical conductors may function to electrically couple a second package 110b. Second package 110b may be positioned above first package 110a in a stacked configuration. In some embodiments, package 110b may include a substrate 120b, a die 130b, and multiple sets of electronic conductors 140. Substrate 120b may include a third surface 180 and a fourth surface 190. The first and second surface of the substrate may be positioned opposite one another. The first surface may include a fourth set of electrical conductors 140d. The fourth set of electrical conductors may be in direct contact with the third set of electrical conductors 140c when the package 110b is assembled to the package 110a. The conductors 140d may be BGA solder balls, in an embodiment.

The fourth set of electrical conductors 140d may function to electronically couple package 110b to package 110a. Thus, the wire loops previously used to couple die together may be avoided. Accordingly, the large loop inductance that wire loops may experience may be avoided, in some embodiments. Limitations in the number of connections and limitations in power delivery that occur when wire loops are used may also be avoided, in some embodiments. Additionally, the illustrated embodiment permits multiple chips to use flip-chip packaging without using TSV technologies.

This packaging method provides a stackable and hence scalable package solution to circumvent the electrical inferiority of wirebond packages and the lack of scalability/stackability of conventional flip chip packages. Two dies may currently be the most economical stack, but the solution is scalable to more than two dies.

Package 110b may include a second die 130b electrically connected to the fourth surface of the second substrate. In some embodiments, a die may be connected to a substrate using a fifth set of electrical conductors 140e (which may be C4 bumps on the die 130b, in an embodiment). The fifth set of electrical conductors may function to electrically connect to at least some of the fourth set of electrical conductors 140d (and through conductors 140d and 140c to conductors 140a). Accordingly, the connections within the substrate 120b may differ from the connections within the substrate 120a, in the illustrated embodiment.

In some embodiments, package 110b may include a sixth set of electrical conductors 140f. The sixth set of electrical conductors may be coupled to the fourth surface of the second substrate. The sixth set of electrical conductors may function to electrically connect to at least some of the first set of electrical conductors 140a (through the conductors 140c and 140d in the illustrated embodiment).

In some embodiments, package 110b may include a compound 170 to substantially cover the fourth surface of the second substrate. The compound may at least substantially cover the second die. The compound may substantially cover most of the sixth set of electrical conductors. In some embodiments, the compound may include an insulating compound which functions to substantially encapsulate at least an upper portion of the package.

Similar to the third set of electrical conductors, the sixth set of electrical conductors may have a first side and a second side. The first side may be in contact with the fourth surface of the second substrate. The second side may be positioned opposite the first side and be substantially exposed (i.e., not covered and/or encapsulated by insulating compound. Exposing at least a portion of the sixth set of conductors may allow the sixth set of conductors to electrically couple package 110b to another electronic module or component. The sixth set of conductors may electrically couple an electronic module or component to another electronic module or component through the fourth and/or first set of electrical conductors. In some embodiments, the sixth set of electrical conductors may electrically couple package 110b to a third package 110c. FIG. 2 depicts an embodiment of three packages 110a-c stacked to form electronic memory module 100.

Although any number of packages may be stacked to form an electronic memory module including two packages (e.g., as depicted in FIG. 1), three packages (e.g., as depicted in FIG. 1), or more than three packages, an electronic memory module may in some embodiments only include two packages. The desired number of packages may be controlled by the ultimate use of the electronic memory module. Spatial constraints may limit the number of packages as regards the amount of space that the electronic memory module will have where it is ultimately used (e.g., cell phones, tablets, etc. are severely limited in the amount of available space).

Many of the embodiments discussed previously herein use some of the classical packaging technologies (e.g., ball grid arrays). In some embodiments, embodiments comprising the stacked die interconnection technology may be applied to fan-out wafer level chip scale packaging. FIG. 5 depicts an embodiment of a portion of an electronic memory module 100 including at least four dies 130 in a fan-out configuration. At least some of the electrical conductors are not depicted for the sake of clarity. FIG. 6 depicts an embodiment of a top view of an electronic memory module 100. At least four dies are depicted (using broken lines) in a fan-out configuration as seen through insulating compound. Fan-out configuration herein referring to products wherein most, if not all, of the process steps for the generation of a package are performed on the wafer.

Fan-out configuration packages may be use similar electrical coupling methods as previously described herein such that the packages may be stacked as well to form electronic memory modules. In some embodiments, a top package of a fan-out configuration memory module may not include electrical conductors positioned on the upper surface of the substrate. In some embodiments, a fan-out configuration may include substrate 120 which is significantly thinner and may only contain a few redistribution layers (e.g., 1-2).

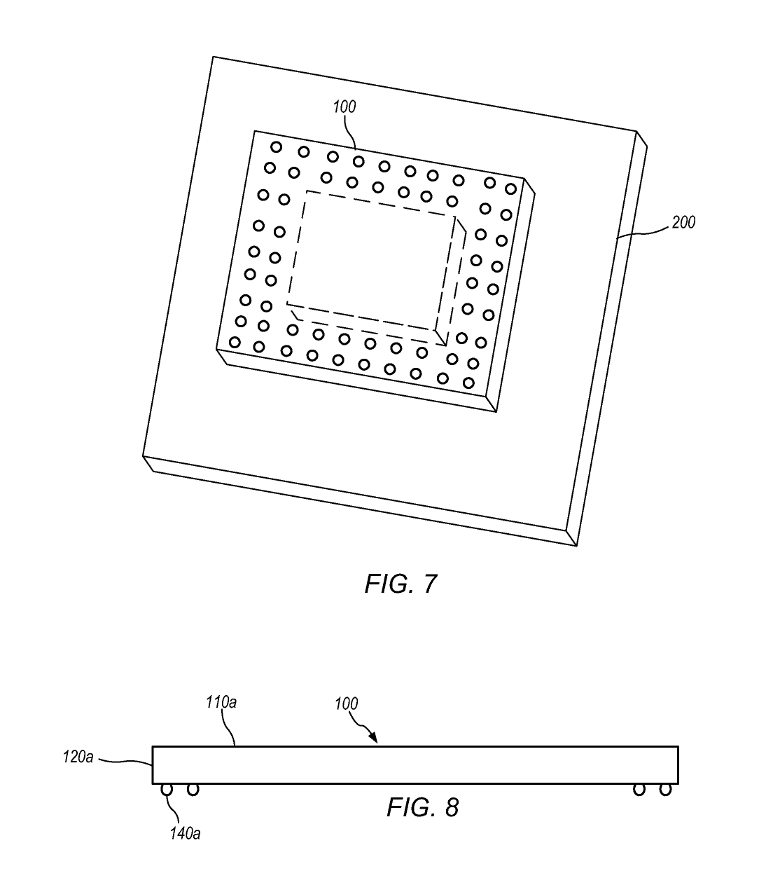

Electronic memory modules discussed herein may be used in a number of electronic devices including personal computers, cell phones, etc. FIG. 7 depicts an embodiment of a top perspective view of an electronic memory module 100 mounted on a motherboard 200. In other embodiments, the memory module 100 may be coupled to another component (e.g., an SOC or other integrated circuit chip in a separate package) using package-on-package configurations.

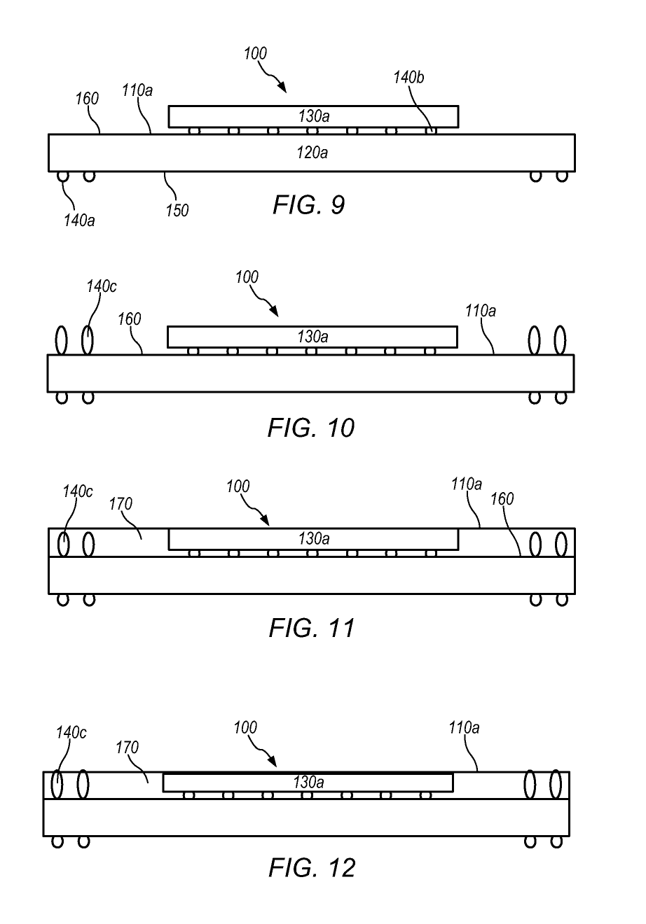

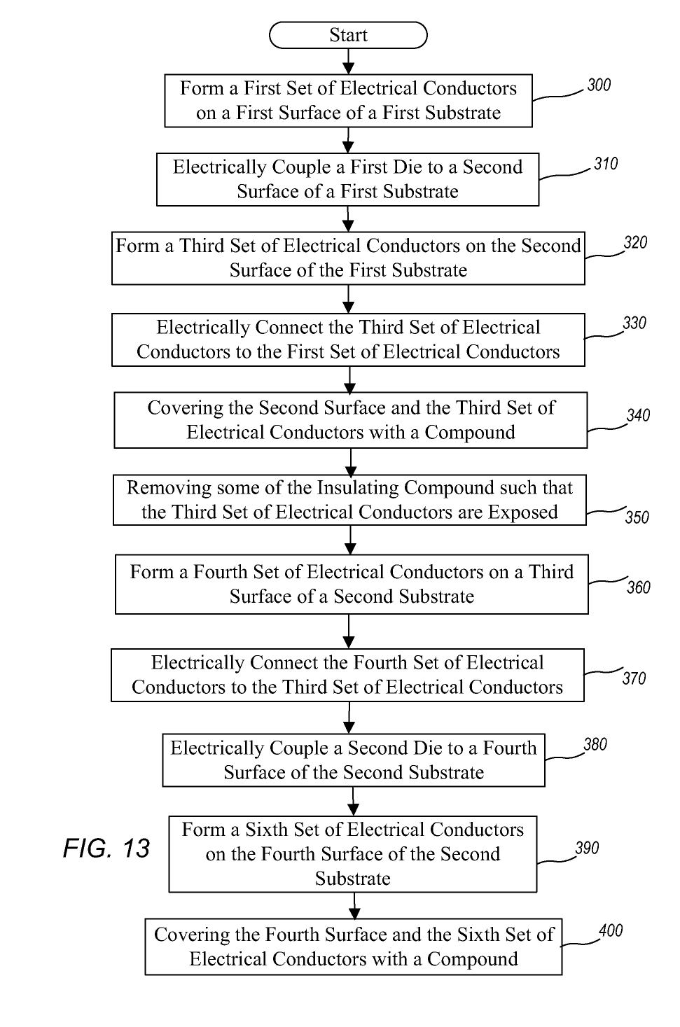

Electronic memory modules described herein may be produced using a number of different manufacturing techniques. An outline of a general method of producing is depicted in FIG. 8-FIG. 13. FIG. 8-FIG. 12 depict an embodiment of different stages of a method of producing a package 110 of an electronic memory module 100. FIG. 13 depicts an embodiment of flow chart representing a method of forming a package 110 of an electronic memory module 100.

In some embodiments, a method of forming an electronic memory module may include forming a first package. Forming the first package of the electronic memory module may include a first set of electrical conductors 140a (e.g., as depicted in FIG. 8) on a first surface 150 of a first substrate 300. The first set of electrical conductors may electrically connect, during use, the electronic memory module. The first set of electrical conductors may electrically connect, during use, the electronic memory module to any number of electronic components (e.g., a motherboard).

Electrical connection between electronic memory module 100 and an electronic component via electrical conductors 140a may be accomplished using various interconnect formats. For example, embodiments of module 100 may include module 100 and an electronic component electrically coupled using ball grid array, pin grid array, land grid array, dual in-line package, or other suitable interconnect form factors. In some cases, embodiments of module 100 may include multiple electrical conductors 140 employing multiple, differing interconnect formats. Electrical conductors 140 may be arranged symmetrically with respect to a surface (e.g., of a substrate, a die, etc.), or may in some cases be arranged asymmetrically with respect to a surface. Different interconnect formats may be used within a single electronic memory module.

The method of forming an electronic memory module may include electrically coupling a first die 130a to a second surface 160, substantially opposite of the first surface, of the first substrate 310. In some embodiments, the first die may be coupled to the first substrate using a second set of electrical conductors 140b (e.g., as depicted in FIG. 8). The second set of electrical conductors may electrically connect, during use, to at least some of the first set of electrical conductors. In some embodiments, the first die may be electrically connected to the first substrate via a flip chip connection.

A flip chip connection may be formed using, for example, ultrasonic of reflow solder processes. In some embodiments, a flip chip connection may be formed using other bumps (e.g., gold stud bumps) and other processes (e.g., conductive film or tape).

Use of flip chip connections provides several advantages over alternative connection methods. For example, flip chip connections may be much shorter than wire bonded connections. Accordingly, designs providing lower inductance values (e.g., power inductance and signal inductance) may be achieved. Furthermore, the availability of an entire side of a die for placement of conductive bumps in a flip chip implementation provides an opportunity for higher conductor density (e.g., a larger number of input/output signals and power/ground signals) than is typically possible with wire bonding.

The method of forming an electronic memory module may include forming a third set of electrical conductors 140c on the second surface 160 of the first substrate 120a (e.g., as depicted in FIG. 8) 320. The third set of electrical conductors may electrically connect, during use, to at least some of the first set of electrical conductors 330.

The method of forming an electronic memory module may include substantially covering the second surface, including at least most of the third set of electrical conductors, of the first substrate with a compound (e.g., as depicted in FIG. 8) 340. In some embodiments, the compound may function to protect at least portions of the package from damage during handling and/or use. The compound may include an electrical insulating compound. The third set of conductors may include a first and a second end. The first end may be coupled to the second surface of the first substrate. The second end of the third set of conductors may remain uncovered by the compound. The second end may remain uncovered such that the second end may electrically connect to another electrical component (e.g., a second package stacked above the first package). In some embodiments, the compound may be applied to the second side of the first package such that at least a portion of the second end of the third set of conductors remains uncovered. The first die may remain covered or uncovered by the compound. In some embodiments, the first die may be covered by the compound in order to protect the die from damage.

In some embodiments, the method of forming an electronic memory module may include removing some of the insulating compound such that at least a portion of the second end of each of the third set of electrical conductors is exposed (e.g., as depicted in FIG. 8) 350. The compound may be removed and hence the electrical conductors exposed by a variety of methods. In some embodiments, lasers may be used to remove the compound precisely where desired. Only enough compound must be removed such that the underlying electrical conductors are revealed and able to make contact with conductors of other electronic components.

In some embodiments, the method of forming an electronic memory module may further include forming a second package. The method may further include forming a fourth set of electrical conductors on a third surface of a second substrate of the second package 360. The method may include electrically connecting the fourth set of electrical conductors to the third set of electrical conductors 370. The method may include electrically coupling a second die to a fourth surface of the second substrate 380, the fourth surface being positioned opposite to the third surface. In some embodiments, a fifth set of electrical conductors may be used to couple the second die to the second substrate. In some embodiments, the second die may be electrically coupled to the second substrate via a flip chip connection. The method may include substantially covering the fourth surface of the second substrate with a compound 400.

In some embodiments, a sixth set of electrical conductors may be coupled to the fourth surface of the second substrate 390. The sixth set of electrical conductors may not be necessary if a component is not going to be electrically coupled to the fourth surface of the second package (e.g., if a third package is not going to stacked on top of the second package). However, even if an electronic memory module is only going to be formed using two stacked packages the sixth set of electrical conductors may be still be added to the second package. Advantages associated with including the sixth set of electrical conductors include that the first and second packages may be substantially identical thereby streamlining manufacturing and decreasing the associated costs.

In some embodiments, electronic memory modules may have a variety of uses. One such embodiment is an electronic memory module be used to provide storage for use by a system-on-a-chip. In some embodiments, an electronic memory module may be configured to a provide separate system memory and graphics memory to a coupled system. In this particular exemplary memory module, the system memory may be provided using one or more of a particular integrated circuit, and the graphics memory may be provided using one or more a different integrated circuit. Other embodiments of electronic module 100 may include integrated circuit dies that provide functionality other than memory, such as, for example, graphics control, digital signal processing, and communication protocol functions.

Although the embodiments above have been described in considerable detail, numerous variations and modifications will become apparent to those skilled in the art once the above disclosure is fully appreciated. It is intended that the following claims be interpreted to embrace all such variations and modifications.

1. An electronic memory module, comprising:
a first substrate including a first surface, a second surface substantially opposite of the first surface, and a first set of electrical conductors coupled to the first surface configured to electrically connect the electronic memory module;
a first die electrically connected to the second surface of the first substrate using a second set of electrical conductors, wherein the second set of electrical conductors are configured to electrically connect to at least some of the first set of electrical conductors; and
a third set of electrical conductors coupled to the second surface of the first substrate, wherein the third set of electrical conductors are configured to electrically connect to at least some of the first set of electrical conductors; and
an insulating compound covering at least a portion of the second surface of the first substrate, at least a portion of the first die and a portion of at least some of each of the second set of electrical conductors.

2. (canceled)

3. The electronic memory module of claim 1, wherein the first die comprises two or more dies electrically connected to the second surface.

4. The electronic memory module of claim 1, wherein the first die comprises two or more dies electrically connected to the second surface in a fan-out configuration.

5. The electronic memory module of claim 1, further comprising
a second substrate including a third surface, a fourth surface substantially opposite of the third surface, and a fourth set of electrical conductors coupled to the third surface configured to electrically connect to the third set of electrical conductors; and
a second die electrically connected to the fourth surface of the second substrate using a fifth set of electrical conductors, wherein the fifth set of electrical conductors are configured to electrically connect to the fourth set of electrical conductors.

6. The electronic memory module of claim 5, further comprising a sixth set of electrical conductors coupled to the fourth surface of the second substrate.

7. The electronic memory module of claim 5, further comprising a sixth set of electrical conductors coupled to the fourth surface of the second substrate, wherein the sixth set of electrical conductors are configured to electrically connect to at least some of the first set of electrical conductors.

8. The electronic memory module of claim 5, further comprising a sixth set of electrical conductors coupled to the fourth surface of the second substrate, wherein the sixth set of electrical conductors are configured to electrically connect to the fourth set of electrical conductors.

9. The electronic memory module of claim 5, wherein the fourth set of electrical conductors are in contact with the third set of electrical conductors.

10. An electronic memory module, comprising:
a first substrate including a first surface, a second surface substantially opposite of the first surface, and a first set of electrical conductors coupled to the first surface configured to electrically connect the electronic memory module;
a first die electrically connected to the first substrate via a flip chip connection at the second surface of the first substrate;
a second set of electrical conductors coupled to the second surface of the first substrate configured to electrically connect to at least some of the first set of electrical conductors;
a second substrate including a third surface, a fourth surface substantially opposite of the third surface, and a third set of electrical conductors coupled to the third surface of the second substrate configured to electrically connect to the second set of electrical conductors;
a second die electrically connected to the second substrate via a flip chip connection at the fourth surface of the second substrate.

11. The electronic memory module of claim 6, further comprising a fourth set of electrical conductors coupled to the fourth surface of the second substrate configured to electrically connect to the third set of electrical conductors.

12. The electronic memory module of claim 6, wherein the third set of electrical conductors are in contact with the second set of electrical conductors.

13. A method of forming an electronic memory module, comprising:
forming a first set of electrical conductors on a first surface of a first substrate, wherein the first set of electrical conductors electrically connect, during use, the electronic memory module;
electrically coupling a first die to a second surface, substantially opposite of the first surface, of the first substrate using a second set of electrical conductors, wherein the second set of electrical conductors electrically connect, during use, to at least some of the first set of electrical conductors; and
forming a third set of electrical conductors on the second surface of the first substrate, wherein the third set of electrical conductors electrically connect, during use, to at least some of the first set of electrical conductors;
covering at least a portion of the second surface of the first substrate, at least a portion of the third set of electrical conductors, and at least a portion of the first die with an insulating compound; and
removing some of the insulating compound such that at least a portion of each of the third set of electrical conductors is exposed and the portion of the first die remains covered.

14. The method of claim 13, further comprising substantially covering the second surface, including at least most of the third set of electrical conductors, of the first substrate with a compound.

15. (canceled)

16. The method of claim 13, wherein forming the first set of electrical conductors on the first surface of the first substrate comprises coupling the first set of electrical conductors to the first surface of the first substrate.

17. The method of claim 13, wherein forming the third set of electrical conductors on the second surface of the first substrate comprises coupling the third set of electrical conductors to the second surface of the first substrate.

18. A method of forming an electronic memory module, comprising:
forming a first set of electrical conductors on a first surface of a first substrate, wherein the first set of electrical conductors electrically connect, during use, the electronic memory module;
electrically coupling a first die to a second surface, substantially opposite of the first surface, of the first substrate via a flip chip connection at the second surface of the first substrate;
forming a second set of electrical conductors on the second surface of the first substrate, wherein the second set of electrical conductors electrically connect, during use, to at least some of the first set of electrical conductors;
forming a third set of electrical conductors on a third surface of a second substrate, wherein the third set of electrical conductors electrically connect, during use, to the second set of electrical conductors;
covering at least a portion of the second surface of the first substrate, at least a portion of the third set of electrical conductors, and at least a portion of the first die with an insulating compound;
removing some of the insulating compound such that at least a portion of each of the third set of electrical conductors is exposed and the portion of the first die remains covered; and
electrically coupling a second die to a fourth surface, substantially opposite of the third surface, of the second substrate via a flip chip connection at the second surface of the first substrate.

19. (canceled)

20. (canceled)

21. The method of claim 18, further comprising forming a fourth set of electrical conductors on the fourth surface of the second substrate.

22. The method of claim 21, further comprising:
substantially covering the second surface, including at least most of the second set of electrical conductors, of the first substrate with an insulating compound; and
substantially covering the fourth surface, including at least most of the fourth set of electrical conductors, of the second substrate with an insulating compound.

23. The method of claim 21, further comprising:
substantially covering the second surface, including at least most of the second set of electrical conductors, of the first substrate with an insulating compound;
removing some of the insulating compound such that at least a portion of each of the second set of electrical conductors is exposed;
substantially covering the fourth surface, including at least most of the fourth set of electrical conductors, of the second substrate with an insulating compound; and
removing some of the insulating compound such that at least a portion of each of the fourth set of electrical conductors is exposed.

24. The method of claim 18, further comprising forming a fourth set of electrical conductors on the fourth surface of the second substrate, wherein the fourth set of electrical conductors electrically connect, during use, to the third set of electrical conductors.

25. The method of claim 13, further comprising removing some of the insulating compound using a laser.

26. The method of claim 18, further comprising removing some of the insulating compound using a laser.
